(19) United States
(12) Patent Application Publication
(10) Pub. No.: US 2020/0049761 A1
(43) Pub. Date: Feb. 13, 2020

(54) SPRING PROBE WITH GEOMETRIC STACKING METHOD

(71) Applicants: PANG-CHIH LIU, Taoyuan City (TW); CHAO-CHI PENG, Taoyuan City (TW)

(72) Inventors: PANG-CHIH LIU, Taoyuan City (TW); CHAO-CHI PENG, Taoyuan City (TW)

(21) Appl. No.: 16/056,850

(22) Filed: Aug. 7, 2018

(51) Int. Cl. G01R 31/28

(52) U.S. Cl. CPC G01R 31/2886

(57) ABSTRACT

An elastic probe device comprising an insulating substrate and a set of probes, the insulating substrate having signal input and output contacts, the probes being adhered to the contacts on the insulating substrate and perpendicular to the insulating substrate, the probes being stacked up to a required height with triangular modules and circular modules, wherein the triangular modules are stacked at different angles to form a set of elastic probe device.

### BACKGROUND OF THE INVENTION

### Field of the Invention

The present invention relates to an elastic probe device, and more particularly to a probe device that can be used to assist the precision measurement of semiconductor wafers, a probe head can be contacted on the semiconductor wafer test point evenly and accurately for fast and accurate testing and effectively enhancing the efficiency of semiconductor wafer testing.

### Description of the Prior Art

In recent years, the semiconductor industry has developed rapidly and the process technology has advanced by leaps and bounds. At this stage, the transistor channel has been developed to the latest 7 nm process, and the integrated circuit (IC) is getting smaller and smaller, and the number of pins is increasing. In order to extract the wafer signal from microminiature and dense semiconductor wafer pads or bumps to maintain accurate test operation of the semiconductor wafer, it is usually necessary to have a precise probe device for effective direct contacting with the tested semiconductor wafer pads or bumps to increase the test efficiency.

As shown in FIG. 1, it is a conventional probe device for testing semiconductor wafers. The probe device comprises a probe card 10a. The probe card 10a is disposed with a circuit, and a set of probes 11a is disposed on the circuit. The tips of the set of probes 11a directly contact the semiconductor wafer pads or bumps 12a, and the wafer signal is extracted onto the probe card 10a for testing.

### SUMMARY OF THE INVENTION

The conventional probe device for testing semiconductor wafers uses a manual method to dispose tens to hundreds of probes on a probe card according to the positions of the semiconductor wafer pads or bumps to be tested. Thereby, the probes directly contact the semiconductor wafer pads or the bumps to extract the wafer signal for testing. Such a probe device is manually fabricated, and the probe is bulky, thus the requirements for wafer microminiaturization and high number of pins cannot be met. At the same time, for the sake of making the probes flexible, they are made of high-rigidity metal, such as tungsten, nickel, etc. The dielectric properties of such metals are not good enough, which will easily cause test errors or scratch the semiconductor wafer pads or bumps.

The present invention provides an elastic probe device, comprising an insulating substrate, a set of tens to tens of thousands of probes, the insulating substrate has through-hole contacts, the contacts are arranged correspondingly based on the positions of the tested semiconductor wafer pads or bumps, the set of probes is adhered to the contacts of the insulating substrate and perpendicular to the insulating substrate, and the probes are stacked up to a required height with triangular modules and circular modules, wherein the triangular modules are vertically stacked at different angles to form a set of elastic probe device.

The elastic probe device provided by the present invention is such that, the probes thereof are electroplated by using various composite conductive materials, and the components are copper, nickel, gold, palladium, tin, etc. Because of the various materials included, the probes have high conductivity, high rigidity and high wearout-resistance. At the same time, the probes are perpendicular to the object to be tested, so that the probe heads and test points of the tested object have the largest contact areas, which effectively reduce the contact impedance and heat value. Further, the probes are vertically stacked at different angles with the triangular modules and the circular modules, thereby forming a set of elastic probes. The probe structure of this form has uniform torque, no offset or deformation when being pressed, and the tips of the probes are aligned accurately with the test points of the tested object, and the overall coplanarity is excellent. At the same time, the probes are electroplated by micro-image exposure forming method, the volume is microminiaturized, and even more microminiature and fine test points can be measured.

### BRIEF DESCRIPTION OF THE DRAWINGS

FIG. 1 is a perspective view of a conventional probe device for testing semiconductor wafers;

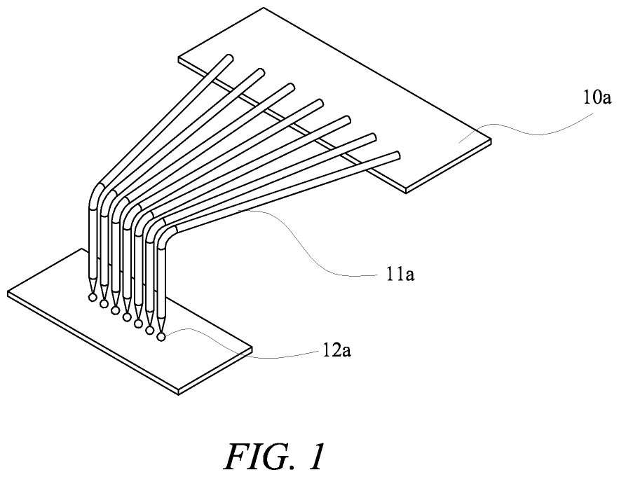

FIG. 2 is a perspective view of the present invention;

FIG. 3 is a perspective exploded view of a probe of the present invention; and

FIG. 4 is a top view of a portion of the probe of the present invention.

### DETAILED DESCRIPTION OF THE PREFERRED EMBODIMENT

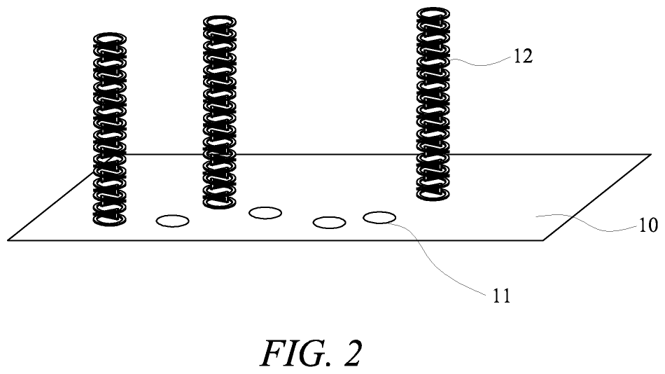

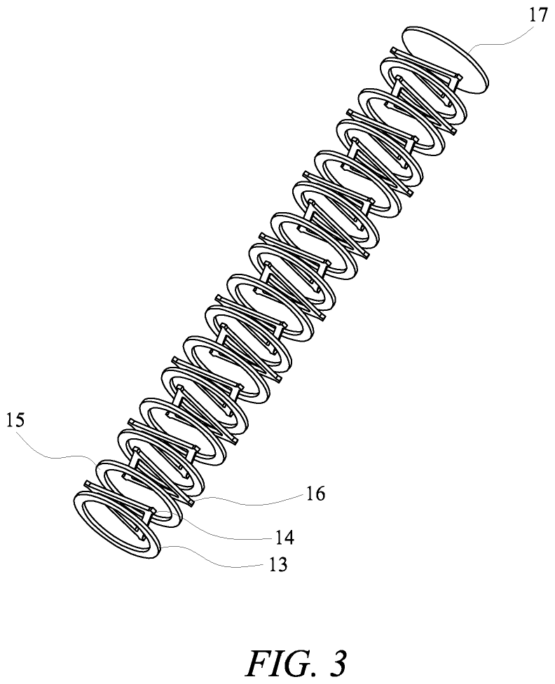

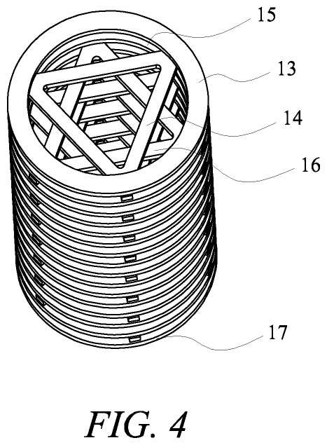

Please refer to FIG. 2, FIG. 3 and FIG. 4. The present invention provides an elastic probe device. The probe device comprises an insulating substrate 10, a plurality of through-hole contacts 11 is disposed on the insulating substrate 10. The contacts 11 are arranged according to the positions of the semiconductor wafer pads or bumps to be tested, and each of the contacts 11 has a probe 12 adhered thereto. The probe 12 is perpendicular to the insulating substrate 10, and the probe 12 is formed by stacking triangular modules and circular modules. A bottom layer of the probe 12 is a circular module 13, the circular module 13 is electroplated on the contact 11 by micro-image exposure forming method; a triangular module 14 is electroplated and stacked on the circular module 13 by micro-image exposure forming method; a circular module 15 is electroplated and stacked on the triangular module 14 by micro-image exposure forming method; and a triangular module 16 is electroplated and stacked on the circular module 15 by micro-image exposure forming method. The triangular module 16 forms a 60 degree angle difference with the triangular module 14. Stacking is repeated in such a way to reach the height required for the probe 12, and a solid circular module 17 is stacked at a topmost layer of the probe 12 as a tip contact of the probe 12, thereby the elastic probe device is formed by the above steps.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. An elastic probe device, comprising:
an insulating substrate, the insulating substrate having signal input and output contacts; and a set of probes, the probes being adhered to the insulating substrate, the probe having a plurality of triangular modules and a plurality of circular modules.

2. The elastic probe device as claimed in claim 1, wherein the triangular modules and the circular modules of the probe are stacked from the bottom to the top in a cross-interval manner perpendicular to the direction of the insulating substrate to connect to the signal input and output contact of the insulating substrate to form a probe body.

3. The elastic probe device as claimed in claim 1, wherein the triangular modules of the probe are cross-stacked at different angles, and between each of the adjacent triangular modules is an angle difference of 60 degrees, thereby forming the elasticity of the probe.
